(19) United States
(12) Patent Application Publication
(10) Pub. No.: US 2021/0207265 A1
(43) Pub. Date: Jul. 8, 2021

(54) Substrate Processing Apparatus and Reaction Tube

(71) Applicant: Kokusai Electric Corporation, Tokyo (JP)

(72) Inventors: Hironori SHIMADA, Toyama (JP); Tomoshi TANIYAMA, Toyama (JP)

(21) Appl. No.: 17/205,815

(22) Filed: Mar. 18, 2021

Related U.S. Application Data
(63) Continuation of application No. PCT/JP2019/036734, filed on Sep. 19, 2019.

(30) Foreign Application Priority Data
Sep. 27, 2018 (JP) 2018-181417

(51) Int. Cl. C23C 16/44; C23C 16/52

(52) U.S. Cl. CPC C23C 16/4412; C23C 16/52

(57) ABSTRACT

According to one aspect of the technique, there is provided a substrate processing apparatus including: a substrate retainer supporting substrates; a reaction tube accommodating the substrate retainer, including: a ceiling closing an upper end thereof; and an opening provided at a lower end thereof; a heater provided around the reaction tube and heating an inside of the reaction tube; a gas supplier supplying a process gas to the substrates; a gas discharger communicating with the inside of the reaction tube and exhausting an inner atmosphere of the reaction tube; and a break filter provided in middle of a gas flow path from the gas supplier to the gas discharger in the reaction tube, disposed more downstream than the substrates along the gas flow path and configured to receive heat from an exhaust gas, wherein an inert gas is supplied into the reaction tube through the break filter.

### CROSS REFERENCE TO RELATED APPLICATIONS

This application is a continuation of International Application No. PCT/JP2019/036734, filed on Sep. 19, 2019, which claims priority under 35 U.S.C. § 119 to Application No. JP 2018-181417 filed on Sep. 27, 2018, the entire contents of which are hereby incorporated by reference.

### TECHNICAL FIELD

The present disclosure relates to a substrate processing apparatus and a reaction tube.

### BACKGROUND

In a manufacturing process of a semiconductor device, a substrate processing apparatus is used to process a substrate under a predetermined temperature and atmosphere to form or modify a film. For example, in a vertical type substrate processing apparatus, a predetermined number of substrates are vertically arranged in a substrate retainer and supported by the substrate retainer. Then, the substrate retainer is transferred (loaded) into a process chamber, and a substrate processing such as a film-forming process is performed on the substrates by supplying a process gas into the process chamber while the substrates are heated by a furnace heater installed around the process chamber.

According to an LP-CVD (Low pressure chemical vapor deposition) method, which is one of typical film-forming methods, the process chamber is depressurized by a vacuum pump, and when the film-forming process is completed, a gas such as nitrogen gas (N₂ gas) is introduced into the process chamber such that an inner pressure of the process chamber returns to an atmospheric pressure. Such a step describe above is also referred to as a vent step. When performing the vent step, a break filter (also referred to as a “diffuser”) provided in the process chamber may be often used to prevent particles from rising up. The break filter removes the particles from the gas introduced thereto and gently discharges the gas through a surface thereof wider than a cross section of a gas supply pipe.

When the break filter described above is provided in the process chamber of the vertical type substrate processing apparatus, since a temperature of the break filter may be low depending on a location where the break filter is installed. Thereby, by-products may adhere to the break filter. Then, a flow rate of the N₂ gas supplied through the break filter so as to prevent the particles adhered to the break filter from rising up may be restricted when performing the vent step. Thereby, it takes time for the inner pressure of the process chamber to return to the atmospheric pressure.

A method of continuously purging the process chamber through the break filter is conceivable in order to prevent the by-products from adhering to the break filter. However, when the N₂ gas is continuously supplied, the N₂ gas may diffuse into the reaction chamber during the film-forming process. As a result, a deviation in the characteristics (for example, a thickness deviation between films formed on each substrate) may occur.

### SUMMARY

Described herein is a technique capable of shortening a time to perform a vent step using a break filter.

According to one aspect of the technique of the present disclosure, there is provided a substrate processing apparatus including: a substrate retainer configured to support a plurality of substrates arranged with a predetermined interval therebetween; a reaction tube in which the substrate retainer is accommodated, including: a ceiling configured to close an upper end thereof; and an opening provided at a lower end thereof and through which the substrate retainer is transferred; a heater provided around the reaction tube and configured to heat an inside of the reaction tube; a gas supplier configured to supply a process gas to the plurality of the substrates supported by the substrate retainer in the reaction tube; a gas discharger configured to communicate with the inside of the reaction tube and to exhaust an inner atmosphere of the reaction tube; and a break filter provided in middle of a gas flow path from the gas supplier to the gas discharger in the reaction tube, disposed more downstream than the plurality of the substrates along the gas flow path and configured to receive heat from an exhaust gas exhausted from the reaction tube, wherein an inert gas is supplied into the reaction tube through the break filter.

### BRIEF DESCRIPTION OF THE DRAWINGS

FIG. 1 schematically illustrates a concept of a substrate processing apparatus according to one or more embodiment described herein.

FIG. 2 schematically illustrates a vertical cross-section of the substrate processing apparatus according to the embodiments described herein.

FIG. 3 is a block diagram schematically illustrating a controller 29 and related components of the substrate processing apparatus according to the embodiments described herein.

FIG. 4 schematically illustrates a horizontal cross-section of a reaction tube 4 of the substrate processing apparatus according to the embodiments described herein.

FIG. 5 is a perspective view schematically illustrating a flange 4C of the substrate processing apparatus according to the embodiments described herein.

FIG. 6 schematically illustrates a vertical cross-section of a substrate processing apparatus according to a modified example of the embodiments described herein.

FIG. 7 is a flow chart schematically illustrating a method of manufacturing a semiconductor device according to the embodiments described herein.

### DETAILED DESCRIPTION

### Embodiments

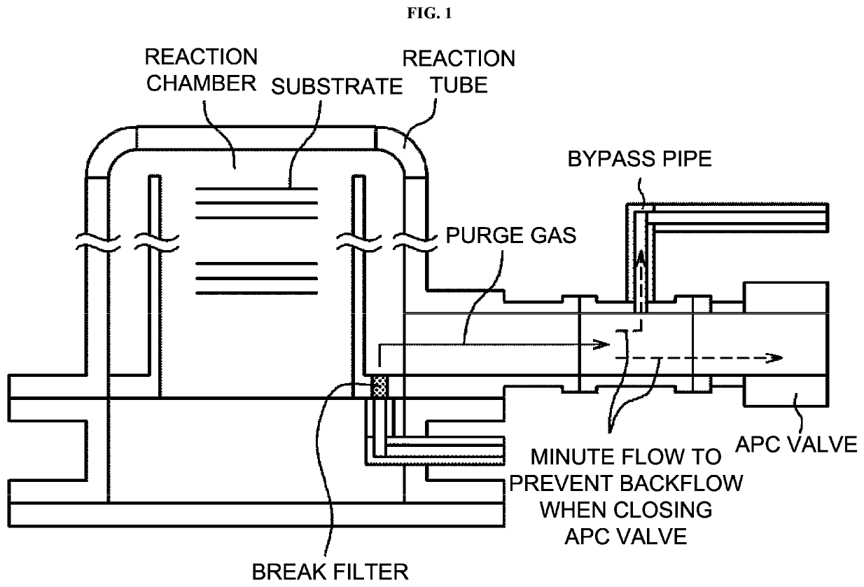

FIG. 1 schematically illustrates a concept of a substrate processing apparatus according to one or more embodiments (hereinafter, simply referred to as “embodiments”) according to the technique of the present disclosure. A break filter is provided at a location where a reaction chamber (also referred to as a “process chamber”) is exhausted. Since the location of the break filter receives the heat from a gas of a high temperature heated in a reaction tube and exhausted from the reaction tube, a temperature of the break filter is high. Thereby, it is possible to suppress by-products from adhering to the break filter. Further, since the location of the break filter is disposed below a substrate and at a downstream side of a gas flow of a process gas, the purge gas hardly diffuses to the substrate even when a small amount of a purge gas is supplied through the break filter. Therefore, by continuously purging the break filter with N₂ gas, it is possible to further suppress the by-products from adhering to the break filter. In addition, since a temperature around the break filter is high, an amount of the by-products adhered around the break filter is small. Therefore, even when a vent step is performed with a large flow rate of the purge gas, it is possible to prevent particles from rising up. In order to prevent a gas passing through a space between the reaction chamber and an APC (Automatic Pressure Controller) valve from flowing back into the reaction chamber, the APC valve may be maintained slightly open. It is more effective when a minute flow rate of the gas is maintained by a bypass flow path by providing a bypass pipe between the reaction chamber and the APC valve.

Hereinafter, various exemplary embodiments according to the technique of the present disclosure will be described in more detail with reference to the accompanying drawings representing some exemplary embodiments. However, the concept of the technique of the present disclosure may be embodied in many different forms, and the technique of the present disclosure is not limited to the exemplary embodiments described herein. Rather, the exemplary embodiments are provided as sufficiently comprehensive and complete descriptions to allow those skilled in the art to practice the technique of the present disclosure.

### Configuration of Substrate Processing Apparatus

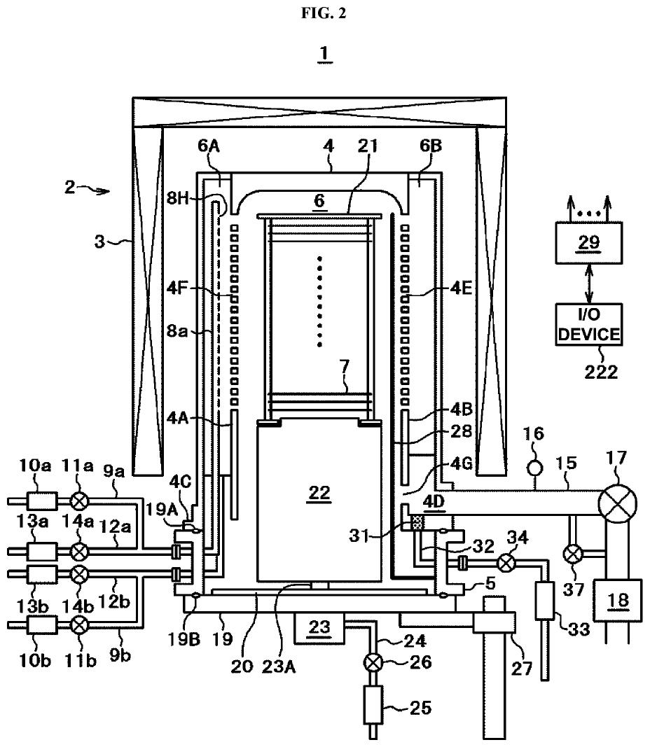

As shown in FIG. 2, a substrate processing apparatus 1 according to the present embodiments is configured as a vertical type heat treatment apparatus (also referred to as a “batch type vertical furnace apparatus”) capable of performing a heat treatment process in a method of manufacturing an integrated circuit.

The substrate processing apparatus 1 includes a process furnace 2. The process furnace 2 includes a heater 3, which is a furnace body serving as a first heating apparatus (heating structure). The heater 3 is of a cylinder shape, and is vertically installed. The heater 3 is configured to heat an inside thereof, and also functions as an activator (which is an activation structure) or an exciter (which is an excitation structure) capable of activating (or exciting) a gas such as a source gas and a reactive gas described later by heat.

A reaction tube 4 constituting a vacuum vessel (also referred to as a “process vessel”) is provided at an inner side of the heater 3 to be aligned in a manner concentric with the heater 3. For example, the reaction tube 4 is made of a heat resistant material such as quartz (SiO₂). The reaction tube 4 is of a cylindrical shape with a closed upper end and an open lower end. That is, the reaction tube 4 includes a ceiling configured to close the upper end thereof and an opening (lower end opening) through which a boat 21 described later is transferred at the lower end thereof. A flange (also referred to as a “lip”) 4C protruding (extending) outward from an outer circumference (outer wall) of the reaction tube 4 is provided at the lower end opening of the reaction tube 4. The flange 4C is connected to a manifold (also referred to as an “inlet flange”) 5 via an O-ring 19A. The manifold 5 is of a short tubular shape with flanges provided at both ends thereof. The manifold 5 is aligned along the same axis as the reaction tube 4 so as to support the reaction tube 4.

A process chamber 6 is constituted by a hollow cylindrical portion of the reaction tube 4. The process chamber 6 is configured to accommodate a plurality of wafers including a wafer 7 serving as a substrate vertically arranged in a horizontal orientation in a multistage manner by the boat 21 described later. Hereinafter, the plurality of the wafers including the wafer 7 may also be simply referred to as wafers 7. A space in which the wafers 7 supported by the boat 21 is accommodated is referred to as a process region, and a space below the process region is referred to as a heat insulating region. A hot wall type reaction tube may be used as the reaction tube 4 to uniformize an inner temperature of the process region of the reaction tube 4.

A supply buffer 6A and an exhaust buffer 6B are provided on the outer wall of the reaction tube 4 at positions facing each other. Each of the supply buffer 6A and the exhaust buffer 6B is provided a space therein, and extends in a height direction so as to face at least the entire process region. Protruding portions of the supply buffer 6A and the exhaust buffer 6B constitute the outer wall of the reaction tube 4, and portions of the reaction tube 4 of a cylindrical shape covered by the supply buffer 6A and the exhaust buffer 6B are configured as a partition 4A and a partition 4B, respectively. In other words, a gas supply space provided in the supply buffer 6A is defined by the outer wall of the reaction tube 4 and the partition 4A, and communicates with the process chamber 6 at a lower end of the supply buffer 6A. On the other hand, a lower end of the exhaust buffer 6B is closed by the flange 4C. The exhaust buffer 6B communicates with an outside of the reaction tube 4 through an exhaust port 4D provided in the vicinity of the lower end of the exhaust buffer 6B. The exhaust port 4D extends continuously from the flange 4C on the flange 4C. Therefore, a gas exhaust space provided in the exhaust buffer 6B is defined by the outer wall of the reaction tube 4, the partition 4B and the flange 4C.

A plurality of gas supply ports 4F is provided at the partition 4A such that the process chamber 6 and the gas supply space fluidically communicate with each other through the gas supply ports 4F. Each of the gas supply ports 4F is of a shape of a horizontally elongated slit, and the gas supply ports 4F are provided at the same interval as that between the wafers 7 in a manner corresponding to surfaces of the wafers 7 in the process region.

A plurality of exhaust outlet ports (which serve as a first exhaust outlet port) 4E is provided at the partition 4B such that the process chamber 6 and the gas exhaust space fluidically communicate with each other through the exhaust outlet ports 4E. Each of the exhaust outlet ports 4E is of a shape of a horizontally elongated slit, and the exhaust outlet ports 4E are provided at the same interval as that between the wafers 7 in a manner corresponding to the wafers 7 in the process region. The exhaust outlet ports 4E are constituted by a plurality of rows of openings provided at positions facing and overlapping the process region in the height direction, and an overall width of the exhaust outlet ports 4E is substantially the same as that of the exhaust buffer 6B. Each of the exhaust outlet ports 4E may be provided at the same height as each of the gas supply ports 4F so as to face each of the gas supply ports 4F. That is, the exhaust outlet ports 4E are provided at positions facing the process region.

A subsidiary exhaust outlet port (also simply referred to as a “sub exhaust outlet port”) 4G serving as a second exhaust outlet port is provided below the exhaust outlet ports 4E of the partition 4B. The sub exhaust outlet port 4G may be provided in the heat insulating region, or may be provided at a position facing a heat insulator 22 which will be described later. The sub exhaust outlet port 4G is of a shape of a horizontally elongated rectangle. An opening area of the sub exhaust outlet port 4G is greater than an opening area of the silt of each of the exhaust outlet ports 4E and smaller than a total opening area of the exhaust outlet ports 4E. The exhaust outlet ports 4E and the sub exhaust outlet port 4G are configured such that the process chamber 6 and the exhaust buffer 6B communicate with each other through the exhaust outlet ports 4E and the sub exhaust outlet port 4G, and are configured such that exhaust an atmosphere of the process region and an atmosphere of the heat insulating region in the process chamber 6 are exhausted through the exhaust outlet ports 4E and the sub exhaust outlet port 4G, respectively. By providing the sub exhaust outlet port 4G in the heat insulating region, it is possible to suppress the diffusion of a shaft purge gas (which will be described later) flowing around the heat insulator 22 into the process region. The reaction tube 4 according to the present embodiments may be entirely made of transparent quartz except for locations where a part of the exhaust port 4D or a part of the flange 4C is provided. In the present specification, “transparent quartz” refers to quartz that has not been subject to a process based on scattering light such as a sand blasting process, a microcrack process and an air bubble process.

A plurality of nozzles such as nozzles 8a, 8b, and 8c are provided in the gas supply space of the supply buffer 6A. A gas supply pipe 9a is connected to a lower end of the nozzle 8a. A mass flow controller (MFC) 10a serving as a flow rate controller (flow rate control structure) and a valve 11a serving as an opening/closing valve are sequentially provided in order at the gas supply pipe 9a from an upstream side toward a downstream side of the gas supply pipe 9a. A gas supply pipe 12a through which an inert gas is supplied is connected to the gas supply pipe 9a at a location more downstream than the valve 11a. A mass flow controller (MFC) 13a and a valve 14a are sequentially provided in order at the gas supply pipe 12a from an upstream side toward a downstream side of the gas supply pipe 12a. The nozzles 8b and 8c are provided with a similar configuration. Hereinafter, the nozzles 8a, 8b and 8c may be collectively or individually referred to as a nozzle 8.

A process gas supplier (which is a process gas supply system) is constituted mainly by the gas supply pipe 9a, the MFC 10a and the valve 11a. An inert gas supply supplier (which is an inert gas supply system) is constituted mainly by the gas supply pipe 12a, the MFC 13a and the valve 14a. The process gas supplier may further include the inert gas supply supplier. A gas supplier (which is a gas supply system) is constituted mainly by the nozzles 8a and 8b, the gas supply ports 4F and the supply buffer 6A. The gas supplier may further include the process gas supplier and the inert gas supply supplier.

The nozzle 8 is provided (installed) in the gas supply space of the supply buffer 6A, and extends from a lower portion of the reaction tube 4 toward an upper portion of the reaction tube 4 along a stacking direction of the wafers 7. The nozzle 8 is provided beside the wafers 7 in parallel to the stacking direction of the wafers 7. A plurality of gas ejection holes 8H are provided at a side surface of the nozzle 8 according to the present embodiments so as to supply the gas to the entirety of the process region. Each of the gas ejection holes 8H may be opened to face a center of the reaction tube 4 at the same interval as that (arrangement interval) between the wafers 7. As a result, it is possible to supply the gas toward each of the wafers 7 along straight paths from each of the gas ejection holes 8H to each of the wafers 7 via the gas supply ports 4F.

The exhaust port 4D is an opening through which the inside and the outside of the reaction tube 4 communicate with each other. An exhaust pipe 15 through which an inner atmosphere of the process chamber 6 is exhausted is connected to the exhaust port 4D. A vacuum pump 18 serving as a vacuum exhaust apparatus is connected to the exhaust pipe 15 via a vacuum gauge 16 capable of detecting an inner pressure of the process chamber 6 and an APC (Automatic Pressure Controller) valve 17. The vacuum gauge 16 serves as a pressure detector (also referred to as a pressure meter) and the APC valve 17 serves as an opening/closing valve. An exhauster (which is an exhaust system) is constituted mainly by the exhaust pipe 15, the vacuum gauge 16, the APC valve 17 and the vacuum pump 18. An outer periphery of the exhaust pipe 15 may be heated by a heater (not shown) in order to prevent components of the gas exhausted from the reaction tube 4. Hereinafter, the gas exhausted from the reaction tube 4 may also referred to as an “exhaust gas”.

An opening degree of the APC valve 17 is controlled by a controller 29. With the vacuum pump 18 in operation, the APC valve 17 may be opened or closed to vacuum-exhaust the process chamber 6 or stop the vacuum exhaust. With the vacuum pump 18 in operation, the opening degree of the APC valve 17 may be continuously adjusted based on pressure information detected by the vacuum gauge 16, in order to control (adjust) the inner pressure of the process chamber 6 to a target value (target pressure). That is, a constant pressure control of controlling the inner pressure of the process chamber 6 to the target pressure is performed by the APC valve 17. A gas discharger (which is a gas discharging system) is constituted mainly by the exhaust outlet ports 4E, the sub exhaust outlet port 4G, the exhaust buffer 6B, the exhaust port 4D, the exhauster and a subsidiary exhaust valve (also simply referred to as a “sub exhaust valve”) 37 described later.

A cap 19 serving as a furnace opening lid capable of airtightly sealing a lower end opening of the manifold 5 is provided under the manifold 5. The cap 19 is capable of supporting the boat 21 directly or indirectly. The cap 19 is made of a metal, and is of a disk shape. An O-ring 19B serving as a seal is provided on an upper surface of the cap 19 so as to be in contact with a lower end of the manifold 5. In addition, a seal cap plate 20 configured to cover and protect the cap 19 is installed on the upper surface of the cap 19 in a region inner than the O-ring 19B.

The cap 19 is in contact with the lower end of the manifold 5 from thereunder. The cap 19 may be moved upward or downward in the vertical direction by a boat elevator 27 provided outside the reaction tube 4 vertically. The boat elevator 27 serves as an elevator. The boat elevator 27 also serves as a transfer device (transfer structure) that transfers the boat 21 and the wafers 7 accommodated in the boat 21 into or out of the process chamber 6.

The boat 21 serving as a substrate retainer is configured to support the wafers 7 (for example, 5 to 200 wafers) vertically in a multistage manner while the wafers 7 are horizontally oriented with their centers aligned with each other. That is, the wafers 7 are arranged with a predetermined interval therebetween. For example, the boat 21 is made of a heat resistant material such as quartz and SiC.

The heat insulator 22 is provided between the boat 21 and the cap 19. For example, the heat insulator 22 may be of a cylindrical shape, or may be embodied by insulating plates (not shown) of a disk shape arranged vertically in a multistage manner. According to the present embodiments, for example, most of the heat insulator 22 above the flange 4C may be constituted by transparent quartz or a semiconductor wafer transparent to far infrared rays.

A rotator 23 is airtightly provided outside of the cap 19 so as to rotatably support the heat insulator 22 by a rotating shaft 23A penetrating the cap 19. The rotating shaft 23A is sealed with a magnetic fluid. A gas supply pipe 24 through which the shaft purge gas of protecting the seal is mainly supplied is connected to the rotator 23. A mass flow controller (MFC) 25 and a valve 26 are sequentially provided in order at the gas supply pipe 24 from an upstream side toward a downstream side of the gas supply pipe 24. A purge gas supplier (which is a purge gas supply system) is constituted mainly by the gas supply pipe 24, the MFC 25 and the valve 26. The purge gas supplier is configured to supply the shaft purge gas from a location in a lower portion of the heat insulating region toward an upper portion of the heat insulating region. For example, after passing through the cap 19, the shaft purge gas flows between the heat insulator 22 and the seal cap plate 20, an inner circumference of the manifold 5 or an outer circumference of the heat insulator 22, and is exhausted through the sub exhaust outlet port 4G.

A temperature detector 28 is installed at the process chamber 6. The temperature detector 28 may be embodied by a plurality of thermocouples arranged in a vertical array. The state of electric conduction to the heater 3 may be adjusted based on temperature information detected by the temperature detector 28 such that a desired temperature distribution of an inner temperature of the process chamber 6 can be obtained.

The controller 29 is constituted by a computer configured to control the entire substrate processing apparatus 1. The controller 29 is electrically connected to the components of the substrate processing apparatus 1 such as the MFCs 10a, 13a and 25, the valves 11a, 14a and 26, the vacuum gauge 16, the APC valve 17, the sub exhaust valve 37, the vacuum pump 18, the heater 3, the temperature detector 28, the rotator 23 and the boat elevator 27, and is configured to receive signals from the components described above or to control the components described above.

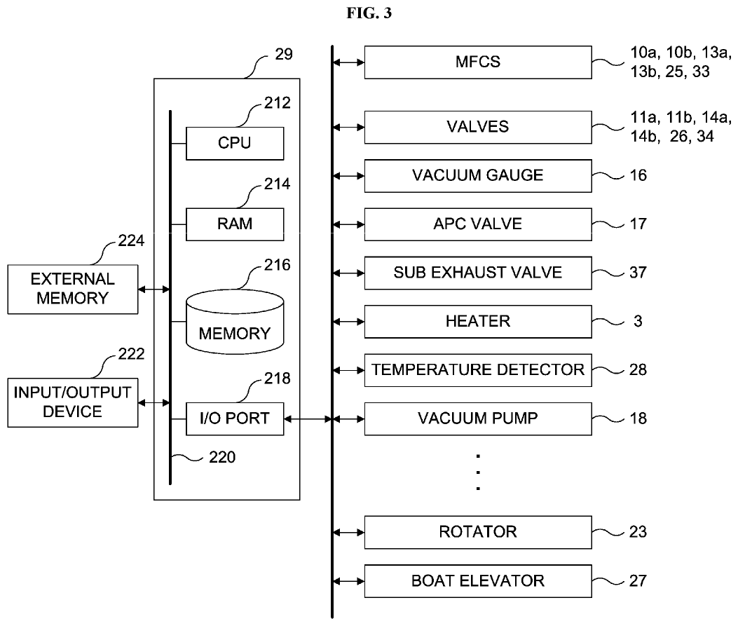

As shown in FIG. 3, the controller 29 of the substrate processing apparatus 1 is constituted by a computer including a CPU (Central Processing Unit) 212, a RAM (Random Access Memory) 214, a memory 216 and an I/O port 218. The RAM 214, the memory 216 and the I/O port 218 may exchange data with the CPU 212 through an internal bus 220. For example, an input/output device 222 such as a touch panel or an external memory 224 such as a thumb memory may be connected to the controller 29.

The memory 216 is configured by components such as a flash memory and a hard disk drive (HDD). For example, a control program for controlling the operation of the substrate processing apparatus 1 or a process recipe containing information on the sequences and conditions of a substrate processing (for example, a film-forming process) described later may be readably stored in the memory 216. The process recipe is obtained by combining steps of the substrate processing described later such that the controller 29 can execute the steps to acquire a predetermine result, and functions as a program. Hereafter, the process recipe and the control program may be collectively or individually referred to as a “program”. In the present specification, the term “program” may indicate the process recipe alone, may indicate the control program alone, or may indicate both of the process recipe and the control program. The RAM 214 functions as a memory area (work area) where a program or data read by the CPU 212 is temporarily stored.

The I/O port 218 is connected to the above-described components such as the MF Cs 10a, 13a and 25, the valves 11a, 14a and 26, the vacuum gauge 16, the vacuum pump 18, the heater 3, the temperature detector 28, the rotator 23 and the boat elevator 27.

The CPU 212 is configured to read the control program from the memory 216 and execute the read control program. In addition, the CPU 212 is configured to read the process recipe from the memory 216 according to an operation command inputted from the input/output device 222. According to the contents of the read process recipe, the CPU 212 may be configured to control various operations such as flow rate adjusting operations for various gases by the MF Cs 10a, 13a and 25, opening and closing operations of the valves 11a, 14a and 26, an opening closing operation of the APC valve 17, a pressure adjusting operation of the APC valve 17 by a valve controller (not shown), a start and stop of the vacuum pump 18, a temperature adjusting operation of the heater 3 based on the temperature detector 28, an operation of adjusting rotation and rotation speed of the boat 21 by the rotator 23 and an elevating and lowering operation of the boat 21 by the boat elevator 27.

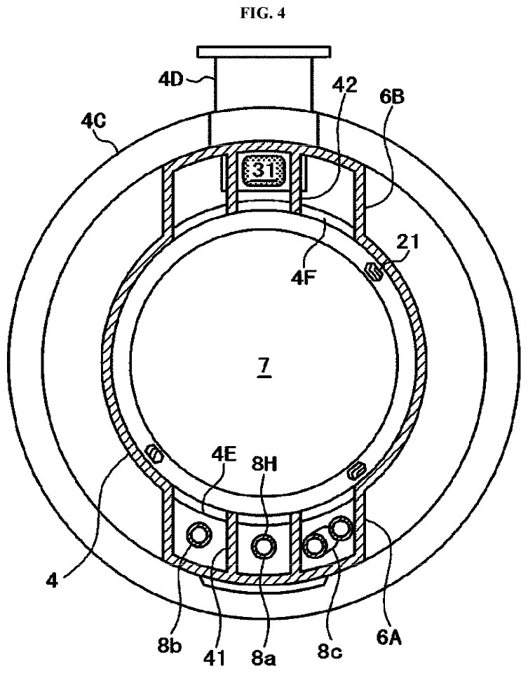

FIG. 4 schematically illustrates a cross-section of the reaction tube 4. The supply buffer 6A of the reaction tube 4 is divided into three nozzle chambers by a partition plate 41, and the nozzles 8a, 8b and 8c are installed in the three nozzle chambers, respectively. A width of each nozzle chamber in a circumferential direction may be set such that a volume of each nozzle chamber is minimized to allow safe installations of several types of nozzles. A lower end of the partition plate 41 extends to the vicinity of the flange 4C below the process region. However, the lower end of the partition plate 41 does not reach a lower end of the flange 4C (see FIG. 2). The exhaust buffer 6B may be similarly divided into three spaces by a partition plate 42. A lower end of the partition plate 42 extends below the process region. However, the lower end of the partition plate 42 does not reach an upper end of the sub exhaust outlet port 4G.

A width of the exhaust buffer 6B in the circumferential direction may be appropriately increased such that a desired exhaust speed can be obtained. For example, the exhaust buffer 6B may be constituted by the outer circumference of the reaction tube 4 except for a portion occupied by the supply buffer 6A. In such a case, the partition plate 42 may be omitted, and the reaction tube 4 may be a complete double tube structure. A break filter 31 is disposed directly below the exhaust buffer 6B. Further, the break filter 31 is provided at a location distanced apart from a central axis (that is, an extension line of the rotating shaft 23A) by a distance greater than a radius of the wafer 7.

As described above, the gas ejection holes 8H open toward the center of the reaction tube 4 are provided at the side surface of each of the nozzles 8a, 8b and 8c. For example, three support columns of the boat 21 are disposed in a gap between an inner circumferential surface of the reaction tube 4 and the wafers 7. It is preferable to minimize an inner diameter of the reaction tube 4 as long as the boat 21 can be safely rotated or transferred into and out of the reaction tube 4. With the boat 21 is loaded, most of the gas ejected through the nozzle 8 flows parallel to the surfaces of the wafers 7 through gaps therebetween so as to flow from one end of each of the wafers 7 to the other end of each of the wafers 7. The reaction tube 4 of such a configuration may also be referred to as a cross-flow tube.

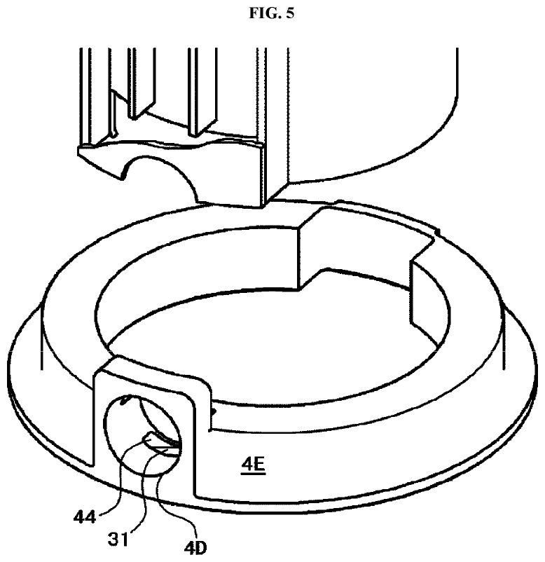

Referring to FIG. 2 again, the break filter 31 is inserted into a hole 44 (see FIG. 5) provided in the flange 4C configured to seal the lower end of the exhaust buffer 6B. A location of the break filter 31 is closer to a core than the outer wall of the reaction tube 4 and an inner circumferential surface of the manifold 5. Thereby, a temperature of the location of the break filter 31 is hot due to the radiant heat from the heater 3 or the heat transferred from the exhaust gas. The break filter 31 is arranged at the location where the exhaust gas that has flowed downward toward the exhaust port 4D in the exhaust buffer 6B is deflected into the horizontal direction. Thereby, a pressure may be locally increased and the heat transfer from the exhaust gas also is increased. A temperature of an upper end surface of the manifold 5 may be limited to 300° C. or lower in order to protect the O-ring 19A. However, a temperature of the break filter 31 can be set higher than that of the manifold 5. The break filter 31 is made of a porous material obtained by sintering and molding fine particles such as alumina, silica and silicon carbide. The break filter 31 is configured such that the gas can flow between an upper surface and a lower surface thereof. With such a structure, the break filter 31 can easily absorb the radiant heat and a heat insulating property of the break filter 31 is higher as compared with that of a bulk structure. When the coefficient of the thermal expansion varies within the flange 4C, the break filter 31 may preferably be gap-fitted into the hole 44 of the flange 4C.

A vent pipe 32 is configured such that N₂ gas (also referred to as a “vent gas”) used in a vent step described later for the inner pressure of the process chamber 6 to return to the atmospheric pressure is introduced into the reaction tube. Thereby, the N₂ gas is supplied to the lower surface of the break filter 31 through the vent pipe 32. An upper end opening of the vent pipe 32 may be provided so as to just cover the lower surface of the break filter 31. When the vent pipe 32 is made of a nickel alloy pipe, an upper end of the vent pipe 32 may be fixed to the break filter 31 by brazing with an outer circumference of the lower surface of the break filter 31, or may be spaced apart from the lower surface of the break filter 31 with a slight gap interposed therebetween. A portion of the vent pipe 32 inside the reaction tube 4 may be integrally connected with the break filter 31 as a single body by being made of the same or similar material as the break filter 31.

A mass flow controller (MFC) 33 and a valve 34 are sequentially provided in order at the vent pipe 32 outside the process chamber 6 from an upstream side toward a downstream side of the vent pipe 32. A vent gas supplier (which is a vent gas supply system) configured to supply the N₂ gas into the break filter 31 is constituted mainly by the vent pipe 32, the MFC 33 and the valve 34. A concentration of oxygen or water vapor in the N₂ gas supplied by the vent gas supplier is set to be sufficiently low. For example, the concentration of oxygen in the N₂ gas is preferably set to be 10 ppm or less.

The sub exhaust valve 37 is provided in parallel with the APC valve 17. The sub exhaust valve 37 constitutes a narrow exhaust path bypassing the APC valve 17. The exhaust path can be opened and closed. A conductance of the exhaust path is set such that, when the APC valve 17 is fully closed during the film-forming process described later, the gas whose flow rate substantially equal to or higher than a flow rate of the vent gas (and the shaft purge gas) flows through the exhaust path. In such a configuration, it is possible to prevent the gases (that is, the vent gas and the shaft purge gas) from flowing into the process region. When a lower limit of the opening degree of the APC valve 17 can be appropriately set during the film-forming process, the sub exhaust valve 37 may be omitted.

FIG. 5 is a perspective view schematically illustrating the flange 4C of the reaction tube 4. A thickness of the flange 4C is set to be thicker than that of the cylindrical portion of the reaction tube 4. The exhaust port 4D is configured as a hole penetrating the flange 4C in a radial direction of the reaction tube 4. The break filter 31 is inserted into the hole 44 penetrating downward from the middle of the exhaust port 4D. In other words, the break filter 31 is arranged on the flange 4C so as to face a flow path of the exhaust port 4D. An upper portion of the hole 44 is open to an inner surface of a curved hole, but the upper surface of the break filter 31 of a flat plate shape does not protrude from the hole 44. The flange 4C surrounding the break filter 31 is integrally connected, as a single body, with the exhaust port 4D or the bottom of the exhaust buffer 6B exposed to the exhaust gas. Therefore, the break filter 31 may be thermally coupled to the flange 4C, the exhaust port 4D or the bottom of the exhaust buffer 6B. That is, the break filter 31 is provided at the bottom of the gas discharger. The flange 4C may be made of opaque quartz. When an exhaust flow rate of the exhaust gas is great, the heat transfer from the exhaust gas is remarkable. The heat transfer from the exhaust gas may increase when a pressure is high even when a flow velocity of the exhaust gas is zero (0).

### MODIFIED EXAMPLE

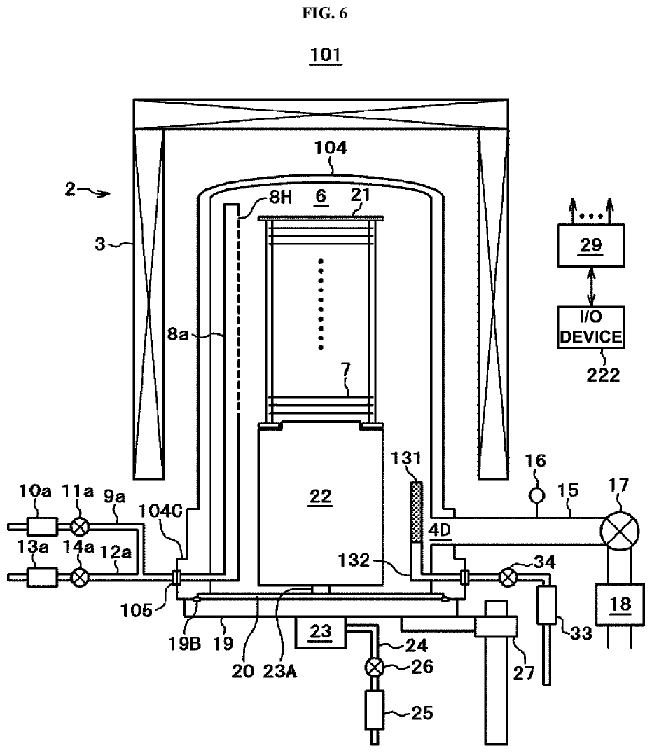

FIG. 6 schematically illustrates a substrate processing apparatus 101 according to a modified example of the embodiments described herein. Components of the substrate processing apparatus 101 other than those particularly described in the following description of the modified example are the same as those of the substrate processing apparatus 1 described above. The same components as those of the substrate processing apparatus 1 will be denoted by like reference numerals, and detailed description thereof will be omitted. According to the modified example, a reaction tube 104 is configured as a single tube of a bell jar shape. The reaction tube 104 is configured as a lip inlet type tube such that the process gas such as the source gas and the reactive gas is introduced through a thick lip (flange) 104C engaged with the cap 19. That is, a plurality of through-holes are radially provided in the lip 104C, and bases of the nozzles 8a, 8b and 8c (for example, a horizontal portion of the nozzle 8a at the lower end thereof) are inserted through the through-holes. The nozzle 8a and the lip 104C may be connected and the nozzle 8a and the gas supply pipe 12a may be connected through a seal joint 105.

A break filter 131 is provided in a tubular shape. The break filter 131 is attached to a tip (front end) of a vent pipe 132 such that a lower end of the break filter 131 is higher than a lower end of a cavity of the exhaust port 4D and an upper end of the break filter 131 is lower than a lower end of the process region. The break filter 131 is provided on a flow path of the process gas from the nozzle 8a to the exhaust port 4D in the process region. The break filter 131 is provided below the wafers 7 and downstream of the wafer 7 along the flow path. Preferably, the break filter 131 is spaced apart from the opening of the exhaust port 4D along an inward direction of the reaction tube 104 closer to the process chamber 6 or provided adjacent to the opening of the exhaust port 4D. The vent pipe 132 is integrally connected with the break filter 131 as a single body, and an inner circumferential portion of the vent pipe 132 may be opaque in order to easily absorb the radiant heat. According to the modified example, the break filter 131 does not receive the heat directly from the exhaust port 4D of a hot temperature. Instead, the break filter 131 is located closer to the process region (or the heater 3) whose temperature is higher than that of the exhaust port 4D, and is configured to disperse the vent gas mainly in the horizontal direction. Similar to the embodiments described above, the break filter 131 is provided closer to a core than an outer wall of the reaction tube 104.

With such a configuration of the break filter 131, it is possible to continuously discharge the vent gas without seriously affecting the film-forming process, and also possible to maintain a temperature of the break filter 131 at a sufficiently high temperature by receiving the radiant heat and the heat transfer so as to prevent the by-products from adhering to the break filter 131. It is also possible to prevent the particles from rising up at the location whose temperature tends to be low such as the inner circumference of the lip 104C and the seal cap plate 20. Although the exhaust port 4D is provided above the lip 104C in FIG. 6, the exhaust port 4D may be provided in an exhaust dedicated manifold (not shown) arranged under the lip 104C. In addition, a part of the configuration of the modified example may be applied to the substrate processing apparatus 1 of FIG. 2. For example, the break filter 131 may penetrate the inside of the exhaust buffer 6B through the hole 44 of the substrate processing apparatus 1.

### Substrate Processing Method Using Substrate Processing Apparatus

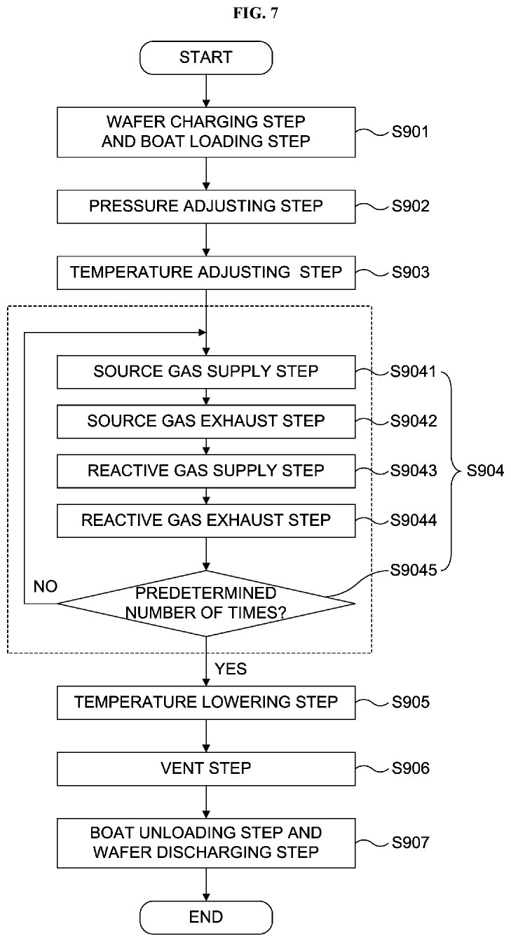

Hereinafter, an exemplary sequence of the substrate processing such as the film-forming process of forming a film on a substrate (that is, the wafer 7), which is a part of a manufacturing process of a semiconductor device, will be described with reference to FIG. 7. The exemplary sequence of the substrate processing is performed using the substrate processing apparatus 1 or the substrate processing apparatus 101. The exemplary sequence of the substrate processing will be described by way of an example in which the film is formed on the wafer 7 serving as the substrate by alternately supplying a first process gas (also referred to as the source gas) and a second process gas (also referred to as the reactive gas) to the wafer 7.

Hereinafter, an example in which a silicon-rich silicon nitride film (hereinafter, also referred to as an “SiN film”) is formed on the wafer 7 by using hexachlorodisilane (Si₂Cl₆, abbreviated as HCDS) gas as the source gas and ammonia (NH₃ ) gas as the reactive gas will be described with reference to FIG. 7. In the following descriptions, the operations of the components constituting the substrate processing apparatus 1 or 101 are controlled by the controller 29.

According to the exemplary sequence of the film-forming process, the SiN film is formed on the wafer 7 by performing a cycle a predetermined number of times (at least once). For example, the cycle may include: a step S9041 of supplying the HCDS gas to the wafer 7 in the process chamber 6; a step S9042 of removing the HCDS gas (residual gas) from the process chamber 6; a step S9043 of supplying the NH₃ gas to the wafer 7 in the process chamber 6; and a step S9044 of removing the NH₃ gas (residual gas) from the process chamber 6. The steps S9041, S9042, S9043 and S9044 of the cycle are non-simultaneously performed.

In the present specification, the term “wafer” may refer to “a wafer itself (a bare wafer)” or may refer to “a wafer and a stacked structure (aggregated structure) of a predetermined layer (or layers) or a film (or films) formed on a surface of the wafer”. Similarly, the term “a surface of a wafer” may refer to “a surface of a wafer itself” or may refer to “a surface of a predetermined layer or film formed on the wafer, that is, a top surface (uppermost surface) of the wafer as a stacked structure”. In the present specification, the term “substrate” and “wafer” may be used as substantially the same meaning. That is, the term “substrate” may be substituted by “wafer” and vice versa.

### S901: Wafer Charging and Boat Loading Step

When a stand-by state of the substrate processing apparatus 1 or 101 is released, the wafers 7 are charged (transferred) into the boat 21 (wafer charging step). Then, the boat 21 charged with the wafers 7 is elevated by the boat elevator 27 and loaded (transferred) into the process chamber 6 (boat loading step). In the step S901, the controller 29 sets a predetermined small flow rate (for example, 50 sccm or less) for the MFC 25 and controls the valve 26 to open. Thereby, a small amount of the N₂ gas (that is, the shaft purge gas) may flow out from the rotator 23. With the boat 21 loaded, the cap 19 airtightly seals the lower end opening of the manifold 5 via the O-ring 19B. The valve 26 or the valve 14a may be opened to supply the purge gas (or the shaft purge gas) from the standby state before the wafers 7 are charged (that is, the purge gas is continuously supplied). Using the shaft purge gas flowing from the valve 26, it is possible to prevent the particles introduced from outside during the wafer charging step from adhering to the heat insulator 22. Using the purge gas flowing from the valve 14a, it is possible to prevent a gas such as air from flowing back into the nozzle.

### S902: Pressure Adjusting Step

The vacuum pump 18 vacuum-exhausts (decompresses and exhausts) the inner atmosphere of the process chamber 6 such that the inner pressure of the process chamber 6 in which the wafers 7 are accommodated reaches and is maintained at a desired pressure (vacuum degree) (pressure adjusting step). When the vacuum pump 18 vacuum-exhausts the inner atmosphere of the process chamber 6, the inner pressure of the process chamber 6 is measured by vacuum gauge 16, and the APC valve 17 is feedback-controlled based on the measured pressure information. The vacuum pump 18 continuously vacuum-exhausts the inner atmosphere of the process chamber 6 until at least the processing of the wafer 7 is completed. In the step S902, the controller 29 sets a predetermined small flow rate (for example, 50 sccm or less) for the MFC 33 and controls the valve 34 and the sub exhaust valve 37 to open. Thereby, a small amount of the N₂ gas (that is, the vent gas) may be discharged through the break filter 31. The vent gas or the shaft purge gas may be exhausted through the sub exhaust valve 37 or the APC valve 17. It is preferable that the vent gas is continuously discharged through the break filter 31 at least while the process gas that generates a solid by-product flows in the process chamber 6. The vent gas may be continuously discharged.

### S903: Temperature Adjusting Step

The heater 3 heats the process chamber 6 such that the temperature of the wafer 7 in the process chamber 6 reaches and is maintained at a predetermined temperature (temperature adjusting step). When the heater 3 heats the process chamber 6, the state of the electric conduction to the heater 3 is feedback-controlled based on the temperature information detected by the temperature detector 28 such that a predetermined temperature distribution of the inner temperature of the process chamber 6 can be obtained. The heater 3 continuously heats the process chamber 6 until at least the processing of the wafer 7 is completed.

### S904: Film-Forming Step

When the inner temperature of the process chamber 6 is stabilized at a predetermined process temperature, the film-forming step S904 is performed by sequentially performing the following four sub-steps, that is, the steps S9041, S9042, S9043 and S9044. During the film-forming step S904, the rotator 23 continuously rotates the boat 21 and the wafers 7 via the rotating shaft 23A.

### S9041: Source Gas Supply Step

In the source gas supply step S9041, by supplying the HCDS gas to the wafer 7 in the process chamber 6, a silicon-containing layer is formed as a first layer on an outermost surface of the wafer 7. Specifically, the valve 11a is opened to supply the HCDS gas into the gas supply pipe 9a. The flow rate of the HCDS gas supplied into the gas supply pipe 9a is adjusted by the MFC 10a. The HCDS gas whose flow rate is adjusted is then supplied into the process region of the process chamber 6 through the gas ejection holes 8H of the nozzle 8a, the gas supply space of the supply buffer 6A and the gas supply ports 4F, and is exhausted through the exhaust pipe 15 via the exhaust outlet ports 4E, the exhaust buffer 6B and the exhaust port 4D. In the source gas supply step S9041, simultaneously, the valve 14a is opened to supply the N₂ gas into the gas supply pipe 12a. The flow rate of the N₂ gas supplied into the gas supply pipe 12a is adjusted by the MFC 13a. The N₂ gas whose flow rate is adjusted is then supplied into the process region of the process chamber 6 together with the HCDS gas through the gas ejection holes 8H of the nozzle 8a, the gas supply space of the supply buffer 6A and the gas supply ports 4F, and is exhausted through the exhaust pipe 15 via the exhaust outlet ports 4E, the exhaust buffer 6B and the exhaust port 4D.

In the step S9041, the controller 29 performs the constant pressure control with a first pressure as the target pressure. However, in an initial stage of step S9041, the inner pressure of the process chamber 6 is considerably lower than the target pressure. Thus, the APC valve 17 may be fully closed. However, the sub exhaust valve 37 (which is not related to the constant pressure control) remains open, and most of the vent gas and the shaft purge gas are discharged to the vacuum pump 18 through the sub exhaust valve 37. That is, the gas discharger is configured to maintain the exhaust flow rate equal to or great than a predetermined flow rate while a predetermined amount of the vent gas is discharged through the break filter 31. Alternatively, the APC valve 17 may be operated so as not to be fully closed but to allow a minute flow rate of the gas constantly flowing through the APC valve 17.

### S9042: Source Gas Exhaust Step

After the first layer is formed, the valve Ila is closed to stop the supply of the HCDS gas into the process chamber 6, and a pressure control is performed with the APC valve 17 fully opened. As a result, the inner atmosphere of the process chamber 6 is vacuum-exhausted to remove a residual gas such as the HCDS gas in the process chamber 6 which did not react or which contributed to the formation of the first layer from the process chamber 6. In the step S9042, the exhaust gas whose temperature is closed to the inner temperature of the process chamber 6 passes through the exhaust port 4D, and the heat is transferred from the exhaust gas to the exhaust port 4D and its peripheries. As a result, the break filter 31 is maintained at a sufficiently high temperature during the film-forming step S904. The residual gas may be purged by the N₂ gas supplied into the process chamber 6 with the valve 14a maintained open. The flow rate of the purge gas through the nozzle 8a is set such that a partial pressure of a low vapor pressure gas is lower than a saturated vapor pressure in the exhaust path, or such that a flow velocity of the gas is greater than a diffusion speed of the gas in the reaction tube 4. Usually, the flow rate of the purge gas through the nozzle 8a is much greater than those of the vent gas and the shaft purge gas which are small.

### S9043: Reactive Gas Supply Step

After the source gas exhaust step S9042 is completed, the NH₃ gas is supplied to the wafer 7 in the process chamber 6, that is, supplied to the first layer formed on the wafer 7. In the reactive gas supply step S9043, the NH₃ gas is thermally activated and then supplied to the wafer 7. The thermally activated NH₃ gas reacts with at least a portion of the first layer (that is, the silicon-containing layer) formed on the wafer 7 in the source gas supply step S9041. As a result, the first layer is modified (changed) into a second layer containing silicon (Si) and nitrogen (N), that is, a silicon nitride layer. In the reactive gas supply step S9043, valves 11b and 14b (see FIG. 2) are controlled in the same manners as the valves Ila and 14a in the source gas supply step S9041. Specifically, a flow rate of the NH₃ gas is adjusted by an MFC 10b (see FIG. 2). The NH₃ gas whose flow rate is adjusted is then supplied into the process region of the process chamber 6 through the gas ejection holes 8H of the nozzle 8, the gas supply space of the supply buffer 6A and the gas supply ports 4F, and is exhausted through the exhaust pipe 15 via the exhaust outlet ports 4E, the exhaust buffer 6B and the exhaust port 4D. In the step S9043, the controller 29 performs the constant pressure control with a second pressure as the target pressure. For example, the first pressure and the second pressure may be set to a pressure within a range from 100 Pa to 5,000 Pa, preferably from 100 Pa to 500 Pa. Similar to the source gas supply step S9041, the gas discharger is configured to maintain the exhaust flow rate equal to or greater than a predetermined flow rate while the predetermined amount of the vent gas is discharged through the break filter 31.

### S9044: Reactive Gas Exhaust Step

After the second layer is formed, the valve 11b is closed to stop the supply of the NH₃ gas into the process chamber 6, and the constant pressure control with a zero (0) pressure as the target pressure. As a result, the inner atmosphere of the process chamber 6 is vacuum-exhausted to remove a residual gas such as the NH₃ gas in the process chamber 6 which did not react or which contributed to the formation of the second layer from the process chamber 6. In the reactive gas exhaust step S9044, similar to the source gas exhaust step S9042, a small amount of the N₂ gas may be supplied into the process chamber 6 as the purge gas. The ultimate pressure in the source gas exhaust step S9042 or the reactive gas exhaust step S9044 may be 100 Pa or less, preferably may be set to a pressure within a range from 10 Pa to 50 Pa. The inner pressure of the processing chamber 6 may be different from that of the processing chamber 6 in the source gas exhaust step S9042 or the reactive gas exhaust step S9044 by 10 times or more.

### S9045: Performing Predetermined Number of Times

By performing the cycle wherein the steps S9041 through S9044 described above are performed non-simultaneously in order a predetermined number of times (n times), the SiN film with a predetermined composition and a predetermined thickness is formed on the wafer 7. The thicknesses of the first layer and the second layer formed in the steps S9041 and S9043, respectively, may not be self-limiting. Therefore, in order to obtain a stable film quality, it is preferable that the concentration of the gas exposed to the wafer 7 and the supply time (time duration) of the gas exposed to the wafer 7 are precisely controlled with the high reproducibility. The steps S9041 and S9042 or the steps S9043 and S9044 may be performed (repeated) a plurality of times within the cycle.

### S905: Temperature Lowering Step

The temperature lowering step S905 may be optional. In the temperature lowering step S905, the inner temperature of the process chamber 6 is gradually lowered by stopping the temperature adjusting step S903 which is continuously performed during the film-forming step S904 or by re-setting the predetermined temperature of the temperature adjusting step S903 to a lower temperature.

### S906: Vent Step

The inert gas is introduced through the break filter until the inner pressure of the process chamber 6 reaches and is maintained at the atmospheric pressure (that is, the inner pressure of the process chamber 6 returns to the atmospheric pressure). In the step S906, the controller 29 sets a predetermined large flow rate (for example, 2 slm or more) for the MFC 33 and controls the valve 34 to open. When the inner pressure of the process chamber 6 reaches and is maintained at the atmospheric pressure, the controller 29 sets a predetermined small flow rate (for example, 50 sccm or less) for the MFC 33 or controls the valve 34 to be closed. The steps S905 and 5906 may be performed in parallel, or the step S906 may be performed before the step S905.

### S907: Boat Unloading and Wafer Discharging Step

The cap 19 is slowly lowered by the boat elevator 27 and the lower end opening of the manifold 5 is opened. The boat 21 with the processed wafers 7 charged therein is unloaded (transferred) out of the reaction tube 4 through the lower end opening of the manifold 5 (boat unloading step). After the boat 21 is unloaded, the processed wafers 7 are discharged (transferred) from the boat 21 (wafer discharging step) by a transfer device (not shown).

### Other Embodiments

While the technique of the present disclosure is described in detail by way of the embodiments and the modified example described above, the technique of the present disclosure is not limited thereto. The technique of the present disclosure may be modified in various ways without departing from the gist thereof. Those skilled in the art may widely apply the above embodiments to a heat treatment process of the substrate under a depressurized state. For example, the technique of the present disclosure is not limited to the hot wall type reaction tube, and may be applied to a cold wall type reaction tube by using a lamp heating or induction heating. For example, the technique of the present disclosure is not limited to the reaction tube as shown in FIG. 1, the reaction tube with a buffer (duct) as shown in FIG. 2, or the reaction tube of a single tube as shown in FIG. 5, and may be applied to various types of reaction tubes.

As described above, according to some embodiments in the present disclosure, it is possible to shorten the time to perform the vent step using the break filter.

What is claimed is:

1. A substrate processing apparatus comprising:
a substrate retainer configured to support a plurality of substrates arranged with a predetermined interval therebetween;
a reaction tube in which the substrate retainer is accommodated, comprising:
a ceiling configured to close an upper end thereof; and
an opening provided at a lower end thereof and through which the substrate retainer is transferred;
a heater provided around the reaction tube and configured to heat an inside of the reaction tube;
a gas supplier configured to supply a process gas to the plurality of the substrates supported by the substrate retainer in the reaction tube;
a gas discharger configured to communicate with the inside of the reaction tube and to exhaust an inner atmosphere of the reaction tube; and
a break filter provided in middle of a gas flow path from the gas supplier to the gas discharger in the reaction tube, disposed more downstream than the plurality of the substrates along the gas flow path and configured to receive heat from an exhaust gas exhausted from the reaction tube,
wherein an inert gas is supplied into the reaction tube through the break filter.

2. The substrate processing apparatus of claim 1, wherein the inert gas is discharged through the break filter in the gas discharger.

3. The substrate processing apparatus of claim 2, wherein the gas discharger comprises
an exhaust buffer extending in a height direction so as to face an entire process region of the reaction tube in which the plurality of the substrates are accommodated, and
the break filter is provided directly below the exhaust buffer.

4. The substrate processing apparatus of claim 2, wherein the gas discharger comprises
an exhaust port through which the inside of the reaction tube and an outside of the reaction tube fluidically communicate with each other below a process region of the reaction tube in which the plurality of the substrates are accommodated, and
wherein the break filter is spaced apart from an opening of the exhaust port along an inward direction of the reaction tube.

5. The substrate processing apparatus of claim 1, wherein the gas discharger comprises:
an exhaust buffer extending in a height direction so as to face an entire region of the reaction tube in which the plurality of the substrates are accommodated;
an exhaust port through which the exhaust buffer communicates with an outside of the reaction tube and the process gas is exhausted to the outside of the reaction tube.

6. The substrate processing apparatus of claim 1, wherein the gas discharger comprises:
an exhaust buffer extending in a height direction so as to face an entire process region of the reaction tube in which the plurality of the substrates are accommodated;
an exhaust port through which a lower end of the exhaust buffer communicates with an outside of the reaction tube and the process gas is exhausted to the outside of the reaction tube, and
the break filter is provided at a bottom of the gas discharger.

7. The substrate processing apparatus of claim 6, wherein the gas discharger further comprises:
a first exhaust outlet port through which the process region fluidically communicates with the exhaust buffer; and
a second exhaust outlet port provided below the first exhaust outlet port and through which a heat insulating region in the reaction tube fluidically communicates with the exhaust buffer.

8. The substrate processing apparatus of claim 1, further comprising
a flange provided around the opening of the reaction tube and extending inward from an outer wall of the reaction tube around the opening,
wherein the gas discharger includes an exhaust port extending continuously from the flange, and
the break filter is provided on the flange so as to face a flow path of the exhaust port.

9. The substrate processing apparatus of claim 1, further comprising
a manifold of a tubular shape aligned along a same axis as the reaction tube and connected to the opening of the reaction tube,
wherein the break filter is provided inside an inner circumferential surface of the manifold.

10. The substrate processing apparatus of claim 9, further comprising:
a cap capable of sealing a lower end opening of the manifold and supporting the substrate retainer directly or indirectly; and
a rotator capable of rotating the substrate retainer with a rotating shaft penetrating the cap,
wherein the break filter is provided at a location distanced apart from an extension line of the rotating shaft by a distance greater than a radius of the substrate.

11. The substrate processing apparatus of claim 1, wherein a predetermined amount of the inert gas is continuously discharged through the break filter while the gas supplier supplies the process gas that generates by-product, and
the gas discharger is configured to maintain an exhaust flow rate equal to or great than a predetermined flow rate while the predetermined amount of the inert gas is discharged through the break filter.

12. The substrate processing apparatus of claim 1, wherein the gas supplier continuously supplies a predetermined amount of the inert gas to the break filter while supplying the process gas into the reaction tube, and
the gas discharger is configured to maintain an exhaust flow rate equal to or great than a predetermined flow rate while a predetermined amount of the inert gas is discharged through the break filter.

13. The substrate processing apparatus of claim 1, wherein the break filter is provided below the plurality of the substrates.

14. The substrate processing apparatus of claim 1, wherein the break filter is provided at a location in the gas discharger where a flow of the exhaust gas is deflected.

15. The substrate processing apparatus of claim 1, wherein the gas discharger comprises:
a flange defining a lower end thereof; and
an exhaust port extending continuously from the flange,
wherein the break filter is installed into a hole penetrating the flange around the exhaust port.

16. The substrate processing apparatus of claim 1, further comprising
a flange protruding outward from a circumference of the opening,
wherein the gas discharger comprises an exhaust port provided in vicinity of the lower end of the reaction tube and through which the lower end of the reaction tube fluidically communicates with an outside of the reaction tube, and
the break filter is attached to a front end of a vent pipe inserted into a hole penetrating the flange and is spaced apart from the exhaust port along an inward direction of the reaction tube in vicinity of the opening of the exhaust port.

17. The substrate processing apparatus of claim 1, wherein the break filter is formed by molding porous alumina, silica or silicon carbide.

18. A reaction tube accommodating a substrate retainer configured to support a plurality of substrates arranged with a predetermined interval therebetween, comprising:
a ceiling configured to close an upper end thereof;
an opening provided at a lower end thereof and through which the substrate retainer is transferred;
a flange extending outward from an outer wall of the reaction tube around the opening;
a gas discharger comprising:
a gas exhaust outlet port through which the gas discharger fluidically communicate with an inside of the reaction tube; and
an exhaust port extending continuously from the flange on the flange, wherein the gas discharger is configured to exhaust an inner atmosphere of the reaction tube through the gas exhaust outlet port and an exhaust buffer; and
a hole into which a break filter is inserted to be installed at the flange provide around the exhaust port,
wherein the break filter is provided in middle of a gas flow path from a gas supplier to the gas discharger in the reaction tube, disposed more downstream than the plurality of the substrates along the gas flow path and configured to receive heat from an exhaust gas exhausted from the reaction tube, and
an inert gas is supplied into the reaction tube through the break filter.
